(19) United States
(12) Patent Application Publication
(10) Pub. No.: US 2008/0153276 A1
(43) Pub. Date: Jun. 26, 2008

(54) Method for Manufacturing Semiconductor Device

(75) Inventors: Chang Youn Hwang, Icheon-Si (KR); Jae Young Lee, Incheon (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/771,426

(22) Filed: Jun. 29, 2007

(30) Foreign Application Priority Data
Dec. 26, 2006 (KR) 10-2006-0134077

(51) Int. Cl. H01L 21/3205

(52) U.S. Cl. 438/586; 257/E21.294

(57) ABSTRACT

A method for manufacturing a semiconductor device is capable of increasing the size of a landing plug without loss of an insulating film separating the landing plug, and may be advantageously used for reducing contact resistance by enlarging a landing plug contact hole without causing the loss of the insulating film due to a cleaning solution during a wet cleaning process. The semiconductor device manufacturing method includes the steps of: forming a gate over a semiconductor substrate and forming an interlayer insulating film filling spaces between the gates; selectively etching the interlayer insulating film to form a landing plug contact hole; forming a primary landing plug filling the landing plug contact hole preferably by a selective epitaxial growth method; forming, over the gate, a buffer dielectric film of an over-hang structure; and forming, over the primary landing plug, a secondary landing plug as a conductive film.

### CROSS-REFERENCE TO RELATED APPLICATION

The priority benefit of Korean patent application number 10-2006-0134077, filed on Dec. 26, 2007, the disclosure of which is incorporated by reference in its entirety, is claimed.

### BACKGROUND OF THE INVENTION

The invention relates in general to a method for manufacturing a semiconductor device; and, more particularly to a method for forming a landing plug contact (LPC) of a semiconductor device.

In high integrated semiconductor devices, such as in dynamic random access memory (DRAM) cells, for example, which include a transistor and a capacitor, a landing plug contact is used for electrical connection between a doped region of a semiconductor substrate, a bit line, and a storage node.

In spaces between word lines including gates, a space adjacent to the doped region of the semiconductor substrate is filled with a conductive film to form a landing plug contact, which is connected to a bit line contact and a storage node contact.

To form such a landing plug contact, a gate spacer for insulating between the gate and the landing plug contact is formed on a sidewall of a gate on the semiconductor substrate.

An interlayer insulating film is then deposited on an entire surface, and planarized.

Next, the interlayer insulating film is etched, typically by a self-align contact (SAC) etching process, to form a landing plug contact hole that exposes the semiconductor substrate.

A conductive film for the landing plug contact, e.g., a polysilicon film, is then deposited on the landing plug contact hole, to form the landing plug contact.

A planarization process is then performed to separate a neighboring landing plug contacts from each other.

Increasingly high degrees of integration in semiconductor devices have caused a gradual reduction in size of landing plug contact hole. Accordingly, contact resistance has increased, causing failures in devices and deterioration in device properties.

In an attempt to increase the size of a contact, when a landing plug contact hole is formed, a wet etch process may be performed as a post-cleaning process.

However, an interlayer insulating film separating a landing plug may be lost due to use of an etching liquid in the wet etching process. Moreover, more interlayer insulating film may be lost in a pre-cleaning process that is performed before filling a landing plug contact hole with a conductive film, resulting in formation of a bridge between landing plugs.

### SUMMARY OF THE INVENTION

The invention provides a method for manufacturing a semiconductor device, including the steps of: forming a plurality of spaced gates over a semiconductor substrate and forming an interlayer insulating film filling spaces between the gates; selectively etching the interlayer insulating film between neighboring gates to form a landing plug contact hole; forming a primary landing plug filling the landing plug contact hole; forming a buffer dielectric film over the gates; and forming a secondary landing plug electrically connected to the primary landing plug.

In one exemplary embodiment, after the gate forming step, a gate spacer is preferably formed on sidewalls of the gate and over the semiconductor substrate. Also, the interlayer insulating film preferably includes a boro-phospho-silicate-glass (BPSG) film, preferably in a thickness of 3000 Å-8000 Å.

Preferably, the interlayer insulating film is etched under conditions of a power range of 500-2000 W, a pressure range of 10 mT-150 mT and an atmosphere containing gas selected from the group consisting of hydroxyl carbon such as CH₄, hydroxyl fluoro carbon such as CHF₃, O₂, N₂, fluoro carbon such C₄F₆, Ar, and mixtures thereof.

In another exemplary embodiment, a wet cleaning process is performed after the landing plug contact hole forming step, using Buffered Oxide Etchant (BOE) solution including a mixture of sulfuric acid (H₂SO₄) and hydrogen peroxide (H₂O₂).

In a further exemplary embodiment, a post-processing step is performed on a resultant interface after the wet cleaning process, in an atmosphere containing a plasma gas selected from the group consisting of fluoro nitrogen such as NF₃, O₂, He, and a mixed gas thereof.

In a further exemplary embodiment, the buffer dielectric film is shaped such that the interlayer insulating film is protected from the wet cleaning solution.

Preferably, the buffer dielectric film includes an undoped silicate glass (USG) film or a plasma enhanced tetra ethyl ortho silicate (PE-TEOS) film, each preferably being in a thickness range of 300 Å-1500 Å.

In yet another exemplary embodiment, a wet cleaning process is performed after the buffer dielectric forming step.

Preferably, the secondary landing plug is including polysilicon in a thickness range of 1000 Å-3000 Å

Accordingly, the method for manufacturing a semiconductor device is used for preventing the loss of an interlayer insulating film due to a cleaning solution during a subsequent wet cleaning process, by forming a primary landing plug underneath a landing plug contact and forming a buffer dielectric film of an over-hang structure in such a manner to cover the top of each end and sidewalls of an exposed gate and come in contact with the primary landing plug.

The invention will be better understood from the following description. Further, it will be appreciated that the various objectives and advantages of the invention can be realized by various means.

### BRIEF DESCRIPTION OF THE DRAWINGS

FIGS. 1a through 1c are cross-sectional views showing the steps of a method for manufacturing a semiconductor device in accordance with a preferred embodiment of the invention.

### DESCRIPTION OF SPECIFIC EMBODIMENTS

Hereinafter, preferred embodiments of the invention are set forth in detail with reference to the accompanying drawings so that those skilled in the art can easily carry out the invention.

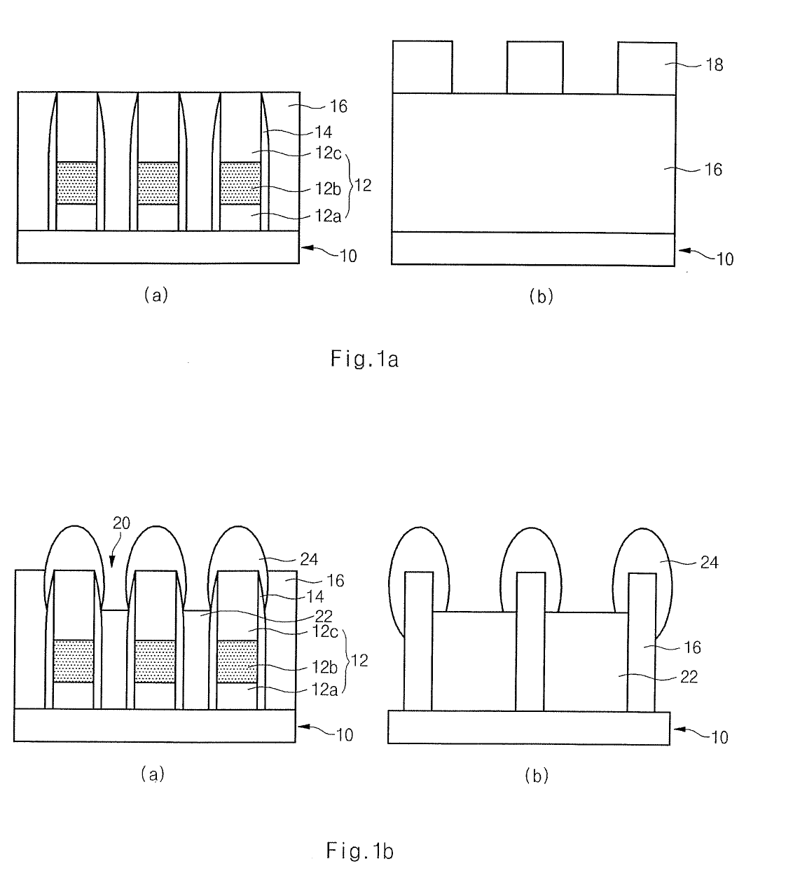

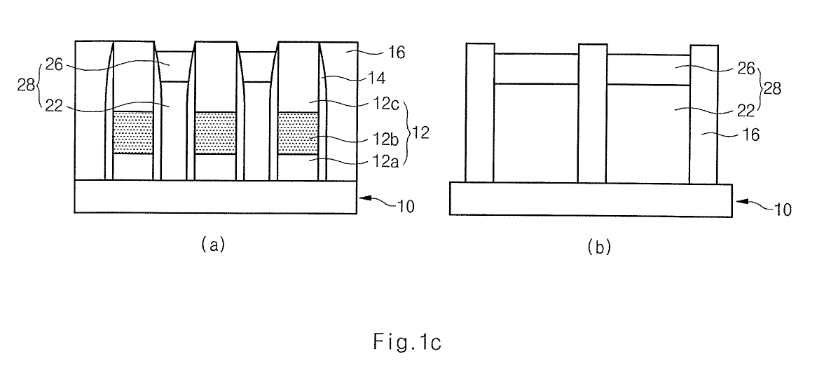

FIGS. 1a through 1c are cross-sectional views showing, in a stepwise fashion, a method for manufacturing a semiconductor device according to a preferred embodiment of the invention, in which (a) is a cross-sectional view and (b) is a side view in each figure.

Referring to FIG. 1a, a gate dielectric film (not shown) is formed over a semiconductor substrate 10 provided with a device isolation film (not shown) that defines an active region.

Next, a gate polysilicon layer (not shown), a gate tungsten layer (not shown), and a gate hard mask layer (not shown) are sequentially formed over the gate dielectric film.

At this time, the gate polysilicon layer is preferably formed in a thickness range of 500 Å-2000 Å, the gate tungsten layer is preferably formed in a thickness range of 500 Å-1500 Å, and the gate hard mask layer is preferably formed in a thickness range of 1000 Å-3000 Å.

Although not shown in the drawing, a barrier metal layer is preferably formed over the gate polysilicon layer. In this case, a laminated structure preferably made up of Ti/WN/TiN, may be formed preferably in a thickness range of 100 Å-500 Å.

Next, a first hard mask layer (not shown) and a first photoresist (not shown) are formed over the gate hard mask layer.

The first hard mask layer is preferably an amorphous Carbon layer.

The first photoresist is then exposed and developed with a gate mask (not shown) to form a first photoresist pattern (not shown).

With the first photoresist pattern as a mask, the first hard mask layer, the gate hard mask layer, the gate tungsten layer, and the gate polysilicon layer are etched to form a first hard mask layer pattern (not shown), a gate hard mask layer pattern 12c, a gate tungsten layer pattern 12b, and a gate polysilicon layer pattern 12a.

Here, the gate hard mask layer is etched, preferably under conditions including a power range of 100-1500 W, a pressure range of 1 mT-20 mT, and a gas atmosphere containing hydroxyl carbon such as CH₄, hydroxyl fluoro carbon such as CHF₃, O₂, Ar, SF₆, or a mixture thereof.

Moreover, the gate tungsten layer is etched, preferably under conditions including a power range of 10 W-1500 W, a pressure range of 2 mT-20 mT, and a gas atmosphere containing fluoro nitrogen such as NF₃, Cl₂, O₂, N₂, He, or a mixture thereof.

The first photoresist pattern and the first hard mask layer pattern are removed to complete the formation of a gate 12 including the gate polysilicon layer pattern 12a, the gate tungsten layer pattern 12b, and the gate hard mask layer pattern 12c.

A nitride film (not shown) is formed on an entire upper surface of the resulting structure, and a spacer processing including etching and cleaning by any suitable means is carried to form a gate spacer 14.

Next, an interlayer insulating film 16 is formed on the entire upper surface of the resulting structure.

The interlayer insulating film 16 is preferably a boro-phospho-silicate-glass (BPSG) film in a thickness range of 3000 Å-8000 Å.

A planarization process is performed until the gate hard mask layer pattern 12c is exposed, in order to render the interlayer insulating film 16 planar.

The planarization process is preferably carried out by a chemical mechanical polishing (CMP) method.

A second hard mask layer (not shown) and a second photoresist (not shown) are then sequentially formed over the interlayer insulating film 16.

The second hard mask layer is preferably an amorphous carbon layer.

The second photoresist is exposed and developed using a landing plug contact mask (not shown), to form a second photoresist pattern 18.

Referring to FIG. 1b, the second hard mask layer and the interlayer insulating film 16 are etched using the second photoresist pattern 18 as a mask, to form a second hard mask layer pattern (not shown) and a landing plug contact hole 20.

Here, the interlayer insulating layer 16 is etched, preferably under conditions including a power range of 500-2000 W, a pressure range of 10 mT-150 mT, and a gas atmosphere containing hydroxyl carbon such as CH₄, hydroxyl fluoro carbon such as CHF₃, O₂, N₂, fluoro carbon such as C₄F₆, Ar, or a mixture thereof.

The second photoresist pattern and the second hard mask layer pattern are removed, and a primary wet cleaning process is then performed.

The primary wet cleaning process is preferably performed using BOE (Buffered Oxide Etchant) solution including a mixture of sulfuric acid (H₂SO₄) and hydrogen peroxide (H₂O₂).

Accordingly, polymer generated while etching the interlayer insulating film 16 is removed, and width of the landing plug contact hole 20 is enlarged.

Next, a post-processing is performed on a resulting interface to remove any residual polymer.

The post-processing is preferably conducted using a plasma gas, for example fluoro nitrogen such as NF₃, O₂, He, or a mixture thereof.

Then, a primary landing plug 22 is formed at a lower part of the landing plug contact hole 20 preferably by a selective epitaxial growth (SEG) method.

The primary landing plug 22 functions as a barrier layer for preventing the loss of the interlayer insulating film 16 during a subsequent secondary wet cleaning process.

A buffer dielectric film 24 of an over-hang structure is formed, covering the top of each end and sidewalls of the exposed gate 12 and coming in contact with the primary landing plug 22.

Here, the buffer dielectric film 24 is shaped such that the interlayer insulating film 16 is protected from the wet cleaning solution

At this time, the buffer dielectric film 24 functions as a barrier layer for preventing the loss of the interlayer insulating film 16 during a subsequent secondary wet cleaning process, and preferably comprises an undoped silicate glass (USG) film or a plasma enhanced tetra ethyl ortho silicate (PE-TEOS) film, either preferably being in a thickness range of 300 Å-1500 Å.

Referring to FIG. 1c, a secondary wet cleaning process is then performed to remove all residuals.

The primary landing plug 22 and the buffer dielectric film 24 prevent the etching solution from infiltrating the interlayer insulating film 16, so that the interlayer insulating film 16 may not be lost.

The buffer dielectric film may be removed by the secondary wet cleaning process.

The landing plug contact hole 20 is then filled with a conductive film to form a secondary landing plug 26, thereby completing the formation of a landing plug 28.

At this time, the conductive film is preferably polysilicon in a thickness range of 1000 Å-3000 Å.

Next, the upper part of the conductive film is planarized and separated from its neighboring landing plug 28 at the same time.

As explained above, the disclosed method for manufacturing a semiconductor device can be advantageously used for preventing the loss of an interlayer insulating film due to the cleaning solution during a subsequent wet cleaning process, by forming the primary landing plug underneath the landing plug contact and forming the buffer dielectric film of an over-hang structure in such a manner to cover the top of each end and sidewalls of the exposed gate and come in contact with the primary landing plug.

The disclosed embodiments of the invention are illustrative and not limiting, and various alternatives and equivalents are possible. The invention is not limited by the type of deposition, etching polishing, and patterning steps described herein, nor is the invention limited to any specific type of semiconductor device. For example, the invention may be implemented in a dynamic random access memory (DRAM) device or nonvolatile memory device. Other additions, subtractions, or modifications to the disclosure are intended to fall within the scope of the appended claims.

What is claimed is:

1. A method for manufacturing a semiconductor device, comprising the steps of:
forming a plurality of spaced gates over a semiconductor substrate and forming an interlayer insulating film filling spaces between the gates;
selectively etching the interlayer insulating film between neighboring gates to form a landing plug contact hole;
forming a primary landing plug filling the landing plug contact hole;
forming a buffer dielectric film over the gates; and
forming a secondary landing plug electrically connected to the primary landing plug.

2. The method of claim 1, further comprising the step of:
after the gate forming step, forming a gate spacer on sidewalls of the gates and over the semiconductor substrate.

3. The method of claim 1, wherein the interlayer insulating film includes a boro-phospho-silicate-glass (BPSG) film in a thickness of 3000 Å-8000 Å.

4. The method of claim 1, comprising etching the interlayer insulating film under the conditions of a power range of 500 W-2000 W, a pressure range of 10 mT-150 mT, and an atmosphere containing gas selected from the group consisting of hydroxyl carbon such as CH₄, hydroxyl fluoro carbon such as CHF₃, O₂, N₂, fluoro carbon such as C₄F₆, Ar, and mixtures thereof.

5. The method of claim 1, further comprising the step of:
after the landing plug contact hole forming step, performing a wet cleaning process using a wet cleaning solution.

6. The method of claim 5, comprising performing the wet cleaning process using Buffered Oxide Etchant (BOE) solution comprising a mixture of sulfuric acid (H₂SO₄) and hydrogen peroxide (H₂O₂).

7. The method of claim 5, further comprising the step of:
after the wet cleaning process, performing a the post-processing using a plasma gas selected from the group consisting of fluoro nitrogen such as NF₃, O₂, He, and mixtures thereof.

8. The method of claim 5, wherein the buffer dielectric film is shaped such that the interlayer insulating film is protected from the wet cleaning solution.

9. The method of claim 1, wherein the buffer dielectric film has an over-hang structure such that the buffer dielectric film contacts the primary landing plug.

10. The method of claim 1, wherein the buffer dielectric film has a thickness in the range of 300 Å-1500 Å.

11. The method of claim 1, wherein the buffer dielectric film is an undoped silicate glass (USG) film or a plasma enhanced tetra ethyl ortho silicate (PE-TEOS) film.

12. The method of claim 1, further comprising the step of:
after the buffer dielectric forming step, carrying out a wet cleaning process.

13. The method of claim 1, wherein the secondary landing plug comprising polysilicon.

14. The method of claim 1, wherein the secondary landing plug has a thickness in the range of 1000 Å-3000 Å.

15. The method of claim 1, comprising forming the primary landing plug by a selective epitaxial growth method.
